(19) United States
(12) Patent Application Publication
(10) Pub. No.: US 2013/0284984 A1
(43) Pub. Date: Oct. 31, 2013

(54) SEMICONDUCTOR BLEND

(71) Applicants: Christopher Newsome, Cambridgeshire (GB); Richard Wilson, Cambridge (GB)

(72) Inventors: Christopher Newsome, Cambridgeshire (GB); Richard Wilson, Cambridge (GB)

(73) Assignee: CAMBRIDGE DISPLAY TECHNOLOGY LIMITED, Cambridgeshire (GB)

(21) Appl. No.: 13/995,176

(22) PCT Filed: Dec. 15, 2011
(86) PCT No.: PCT/GB2011/001722

§ 371 Date: Jun. 17, 2013

(30) Foreign Application Priority Data
Dec. 15, 2010 (GB) 1021277.7

(51) Int. Cl. H01L 51/00

(52) U.S. Cl. CPC H01L 51/0074
USPC 252/500

(57) ABSTRACT

The invention provides an ink comprising a blend of a polymer material and a small molecule semiconductor material dissolved or dispersed in a solvent, said blend comprising at least 70% by weight of said polymer material and wherein the ink concentration is at least 0.4% w/v. The polymer material is preferably TFB [9,9′-dioctylfluorene-co-N-(4-butylphenyl)-diphenylamine]ₙ, and said small molecule semiconductor material preferably has the following formula:

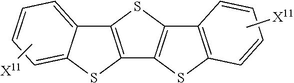

wherein X¹¹ is a group of formula CₙH₂ₙ₊₁ wherein n is an integer of from 4 to 16.

### FIELD OF INVENTION

The present invention relates to semiconductor blends and semiconductor inks having a high proportion by weight of polymer and to semiconducting devices such as organic thin film transistors wherein the semiconducting layer comprises a layer of said semiconductor blend.

### BACKGROUND OF THE INVENTION

Transistors can be divided into two main types: bipolar junction transistors and field-effect transistors. Both types share a common structure comprising three electrodes with a semiconductive material disposed therebetween in a channel region. The three electrodes of a bipolar junction transistor are known as the emitter, collector and base, whereas in a field-effect transistor the three electrodes are known as the source, drain and gate. Bipolar junction transistors may be described as current-operated devices as the current between the emitter and collector is controlled by the current flowing between the base and emitter. In contrast, field-effect transistors may be described as voltage-operated devices as the current flowing between source and drain is controlled by the voltage between the gate and the source.

Transistors can also be classified as p-type and n-type according to whether they comprise semiconductive material which conducts positive charge carriers (holes) or negative charge carriers (electrons) respectively. The semiconductive material may be selected according to its ability to accept, conduct, and donate charge. The ability of the semiconductive material to accept, conduct, and donate holes or electrons can be enhanced by doping the material. The material used for the source and drain electrodes can also be selected according to its ability to accept and inject holes or electrons. For example, a p-type transistor device can be formed by selecting a semiconductive material which is efficient at accepting, conducting, and donating holes, and selecting a material for the source and drain electrodes which is efficient at injecting and accepting holes from the semiconductive material. Good energy-level matching of the Fermi-level in the electrodes with the HOMO (Highest Occupied Molecular Orbital) level of the semiconductive material can enhance hole injection and acceptance. In contrast, an n-type transistor device can be formed by selecting a semiconductive material which is efficient at accepting, conducting, and donating electrons, and selecting a material for the source and drain electrodes which is efficient at injecting electrons into, and accepting electrons from, the semiconductive material. Good energy-level matching of the Fermi-level in the electrodes with the LUMO (Lowest Unoccupied Molecular Orbital) level of the semiconductive material can enhance electron injection and acceptance.

Transistors can be formed by depositing the components in thin films to form thin film transistors. When an organic material is used as the semiconductive material in such a device, it is known as an organic thin film transistor.

Various arrangements for organic thin film transistors are known. One such device is an insulated gate field-effect transistor which comprises source and drain electrodes with a semiconductive material disposed therebetween in a channel region, a gate electrode disposed over the semiconductive material and a layer of insulting material disposed between the gate electrode and the semiconductive material in the channel region.

An example of such an organic thin film transistor is shown in FIG. 1. The illustrated structure may be deposited on a substrate (not shown) and comprises source and drain electrodes 2, 4 which are spaced apart with a channel region 6 located therebetween. An organic semiconductor 8 is deposited in the channel region 6 and may extend over at least a portion of the source and drain electrodes 2, 4. An insulating layer 10 of dielectric material is deposited over the organic semi-conductor 8 and may extend over at least a portion of the source and drain electrodes 2, 4. Finally, a gate electrode 12 is deposited over the insulating layer 10. The gate electrode 12 is located over the channel region 6 and may extend over at least a portion of the source and drain electrodes 2, 4.

The structure described above is known as a top-gate organic thin film transistor as the gate is located on a top side of the device. Alternatively, it is also known to provide the gate on a bottom side of the device to form a so-called bottom-gate organic thin film transistor.

An example of such a bottom-gate organic thin film transistor is shown in FIG. 2. In order to show more clearly the relationship between the structures illustrated in FIGS. 1 and 2, like reference numerals have been used for corresponding parts. The bottom-gate structure illustrated in FIG. 2 comprises a gate electrode 12 deposited on a substrate 1 with an insulating layer 10 of dielectric material deposited thereover. Source and drain electrodes 2, 4 are deposited over the insulating layer 10 of dielectric material. The source and drain electrodes 2, 4 are spaced apart with a channel region 6 located therebetween over the gate electrode. An organic semiconductor 8 is deposited in the channel region 6 and may extend over at least a portion of the source and drain electrodes 2, 4.

The conductivity of the channel can be modulated by the application of a voltage at the gate. In this way the transistor can be switched on and off using an applied gate voltage. The drain current that is achievable for a given voltage is dependent on the mobility of the charge carriers in the organic semiconductor in the active region of the device (the channel region between the source and drain electrodes). Thus, in order to achieve high drain currents with low operational voltages, organic thin film transistors must have an organic semiconductor which has highly mobile charge carriers in the channel region.

There are various compound types that have been developed in recent years that are potentially suitable for use as the semiconductive material in organic thin film transistors. One such class of particular importance is the small molecule semiconductor. These are non-polymeric semiconducting organic molecules. Typical examples include pentacene derivatives and thiophene derivatives.

Although small molecule semiconductor materials can exhibit high mobilities due to their highly crystalline nature (particularly as thermally evaporated thin films) it can often be difficult to obtain repeatable results from solution processed films due to their poor film forming properties. Issues with material reticulation from and adhesion to substrates, film roughness and film thickness variations can limit the performance of these materials in devices. Film roughness can be a further problem for top-gate organic thin film transistor devices, as the accumulation layer is formed at the uppermost surface of the semiconductor layer.

To overcome the problem of the poor film forming properties of the small molecule semiconductor materials, the use of semiconductor blends consisting of small molecules and polymers has been developed. Blends of small molecules with polymers exhibit superior film forming properties to the small molecule component due to the excellent film forming properties of polymer materials.

A few examples of such blends (semiconductor-semiconductor or semiconductor—insulator) in the literature include Smith et. al., Applied Physics Letters, Vol 93, 253301 (2008); Russell et. al., Applied Physics Letters, Vol 87, 222109 (2005); Ohe et. al., Applied Physics Letters, Vol 93, 053303 (2008); Madec et. al., Journal of Surface Science & Nanotechnology, Vol 7, 455-458 (2009); and Kang et. al., J. Am. Chem. Soc., Vol 130, 12273-75 (2008). In these examples, the amount of small molecule semiconductor present in the blend is at least 50% by weight.

WO 2004/057688 discloses blends of various semiconducting polymers and small molecules. Most of the examples show blends with a ratio of polymer:small molecule semiconductor of between 40:60 to 60:40, and preferably 50:50 parts by weight. One example, however, shows a blend with a ratio of polymer:small molecule semiconductor of 70:30, although this is shown to perform less well than the other blends.

There is a need for semiconductor blends with excellent blend forming properties that have lower amounts of the small molecule semiconductors because they are generally more expensive to synthesise and handle and generally have a lower solubility than polymers, which can lead to precipitation in solution.

### SUMMARY OF THE INVENTION

We have surprisingly found that it is possible to address this problem by the production of semiconductor blends having higher proportions of polymer in the blend than those previously described in the prior art. This is achieved by increasing the total solid content of the semiconductor blend, which upon deposition by spin coating results in a film exhibiting much improved properties with a performance comparable to a small molecule rich blend.

According to a first aspect of the present invention, there is provided an ink for inkjet printing or spin coating as specified in claims 1 to 32.

According to a second aspect of the present invention there is provided a method of making said ink as specified in claim 33.

(1) Thus, in a first embodiment a semiconductor blend comprises for example a small molecule semiconductor material and a polymer material, wherein said blend comprises at least 75% by weight of said polymer material.

Preferred examples include:

(2) a semiconductor blend according to (1), wherein said blend comprises from 75 to 85% by weight of polymer material;

(3) a semiconductor blend according to (1) or (2), wherein said polymer material is a semiconducting polymer material;

(4) a semiconductor blend according to (3), wherein said semiconducting polymer material is a conjugated polymer comprising a repeat unit of formula (I)

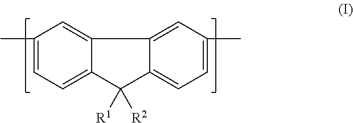

wherein R¹ and R² are the same or different and each is selected from the group consisting of hydrogen, an alkyl group having from 1 to 16 carbon atoms, an aryl group having from 5 to 14 carbon atoms and a 5- to 7-membered heteroaryl group containing from 1 to 3 sulfur atoms, oxygen atoms and/or nitrogen atoms, said aryl group or heteroaryl group being unsubstituted or substituted with one or more substituents selected from an alkyl group having from 1 to 16 carbon atoms and an alkoxy group having from 1 to 16 carbon atoms;

(5) a semiconductor blend according to (4), wherein said semiconducting polymer material is a conjugated polymer comprising the repeat unit (I), wherein R¹ and R² are the same or different and each is selected from the group consisting of hydrogen, an alkyl group having from 1 to 12 carbon atoms and a phenyl group, said phenyl group being unsubstituted or substituted with one or more substituents selected from an alkyl group having from 1 to 12 carbon atoms and an alkoxy group having from 1 to 12 carbon atoms;

(6) a semiconductor blend according to (4), wherein said semiconducting polymer material is a conjugated polymer comprising the repeat unit (I), wherein R¹ and R² are the same or different and each is selected from the group consisting of an alkyl group having from 4 to 12 carbon atoms and a phenyl group, said phenyl group being unsubstituted or substituted with one or more substituents selected from an alkyl group having from 4 to 8 carbon atoms and an alkoxy group having from 4 to 8 carbon atoms;

(7) a semiconductor blend according to any one of (4) to (6), wherein said semiconducting polymer material is a conjugated polymer comprising the repeat unit (I), said polymer further comprising a repeat unit of formula (II):

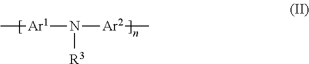

wherein Ar¹ and Ar² are the same or different and each is selected from the group consisting of an aryl group having from 5 to 14 carbon atoms and a 5- to 7-membered heteroaryl group containing from 1 to 3 sulfur atoms, oxygen atoms and/or nitrogen atoms, said aryl group or heteroaryl group being unsubstituted or substituted with one or more substituents selected from an alkyl group having from 1 to 16 carbon atoms and an alkoxy group having from 1 to 16 carbon atoms

R³ is an alkyl group having from 1 to 16 carbon atoms, or an aryl group having from 5 to 14 carbon atoms which is optionally substituted with one or more substituents selected from an alkyl group having from 1 to 16 carbon atoms and an alkoxy group having from 1 to 16 carbon atoms; and n is an integer greater than or equal to 1, preferably 1 or 2;

(8) a semiconductor blend according to (7), wherein each of Ar¹ and Ar² is a phenyl group and R³ is an alkyl group having from 1 to 8 carbon atoms or a phenyl group which may be unsubstituted or substituted with an alkyl group having from 1 to 8 carbon atoms;

(9) a semiconductor blend according to (7), wherein said semiconducting polymer material is TFB [9,9′-dioctylfluorene-co-N-(4-butylphenyl)-diphenylamine]ₙ;

(10) a semiconductor blend according to any one of (1) to (9), wherein said small molecule semiconductor material is selected from the group consisting of substituted pentacenes and organic semiconducting compounds of formula (III):

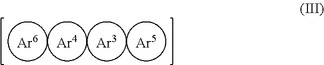

wherein Ar³, Ar⁴, Ar⁵ and Ar⁶ independently comprise monocyclic aromatic rings and at least one of Ar³, Ar⁴, Ar⁵ and Ar⁶ is substituted with at least one substituent X, which in each occurrence may be the same or different and is selected from the group consisting of (i) unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms, or (ii) a polymerisable or reactive group selected from the group consisting of halogens, boronic acids, diboronic acids and esters of boronic acids and diboronic acids, alkylene groups having from 2 to 12 carbon atoms and stannyl groups, and wherein Ar³, Ar⁴, Ar⁵ and Ar⁶ may each be unfused or fused to one or more further monocyclic aromatic rings, and wherein at least one of Ar³, Ar⁴, Ar⁵ and Ar⁶ comprises a 5- to 7-membered heteroaryl group containing from 1 to 3 sulfur atoms, oxygen atoms, selenium atoms, and/or nitrogen atoms;

(11) a semiconductor blend according to (10), wherein Ar⁵ is fused to a further aryl group Ar⁷ to provide a structure of formula (IV):

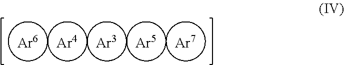

wherein Ar⁷ represents a monocyclic aromatic ring unsubstituted or substituted with one or more substituents X, said monocyclic aromatic ring Ar⁷ preferably being a 5- to 7-membered heteroaryl group containing from 1 to 3 sulfur atoms, oxygen atoms, selenium atoms, and/or nitrogen atoms;

(12) a semiconductor blend according to (11), wherein Ar⁶ is fused to a further aryl group Ar⁸ to provide a structure of formula (V):

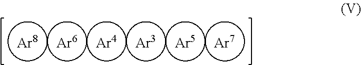

wherein Ar⁸ represents a monocyclic aromatic ring unsubstituted or substituted with one or more substituents X, said monocyclic aromatic ring Ar⁸ preferably being a 5- to 7-membered heteroaryl group containing from 1 to 3 sulfur atoms, oxygen atoms, selenium atoms, and/or nitrogen atoms;

(13) a semiconductor blend according to (12), wherein Ar⁷ is fused to a further aryl group Ar⁹ to provide a structure of formula (VI):

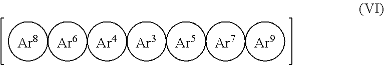

wherein Ar⁹ represents a monocyclic aromatic ring unsubstituted or substituted with one or more substituents X, said monocyclic aromatic ring Ar⁹ preferably being a 5- to 7-membered heteroaryl group containing from 1 to 3 sulfur atoms, oxygen atoms, selenium atoms, and/or nitrogen atoms;

(14) a semiconductor blend according to any one of (10) to (13), wherein the small molecule semiconductor material comprises the structure:

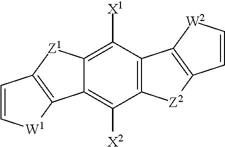

wherein X¹ and X² may be the same or different and are selected from substituents X as defined in (10); Z¹ and Z² are independently S, O, Se or NR⁴; and W¹ and W² are independently S, O, Se, NR⁴ or —CR⁴═CR⁴—, where R⁴ is H or a substituent selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms;

(15) a semiconductor blend according to any one of (10) to (13), wherein the small molecule semiconductor material comprises the structure:

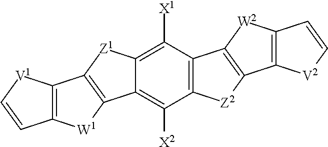

wherein X¹ and X² are as defined in (14), Z¹, Z², W¹ and W² are as defined in (14) and V₁ and V₂ are independently S, O, Se or NR⁵ wherein R⁵ is H or a substituent selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms;

(16) a semiconductor blend according to any one of (10) to (13), wherein the small molecule semiconductor material comprises the structure:

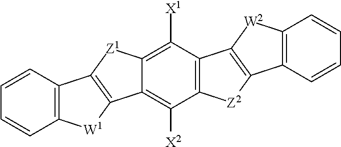

wherein X¹ and X² are as defined in (14) and Z¹, Z², W¹ and W² are as defined in (14);

(17) a semiconductor blend according to any one of (10) to (13), wherein the small molecule semiconductor material comprises the structure:

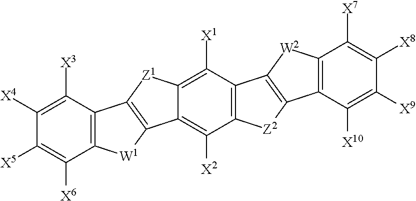

wherein Z¹, Z², W¹ and W² are as defined in (14) and X¹-X¹⁰, which may be the same or different, are selected from substituents X as defined in (10);

(18) a semiconductor blend according to (10), wherein said small molecule semiconductor material is a benzothiophene derivative of formula (VII):

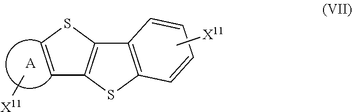

wherein A is a phenyl group or a thiophene group, said phenyl group or thiophene group being unfused or fused with a phenyl group or a thiophene group which can be unsubstituted or substituted with at least one group of formula X¹¹ and/or fused with a group selected from a phenyl group, a thiophene group and a benzothiophene group, any of said phenyl, thiophene and benzothiphene groups being unsubstituted or substituted with at least one group of formula X¹¹; and

each group X¹¹ may be the same or different and is selected from substituents X as defined in (10), and preferably is a group of formula CₙH₂ₙ₊₁ wherein n is 0 or an integer of from 1 to 20;

(19) a semiconductor blend according to (18), wherein said small molecule semiconductor material is a benzothiophene derivative of formula (VII) wherein A is selected from:

a thiophene group that is fused with a phenyl group substituted with at least one group of formula X¹¹; or

a phenyl group that may be unsubstituted or substituted with at least one group of formula X¹¹, said phenyl group further being unfused or fused with a thiophene group which can be unsubstituted or substituted with at least one group of formula X¹¹ and/or fused with a benzothiophene group, said benzothiphene group being unsubstituted or substituted with at least one group of formula X¹¹, wherein X¹¹ is a group of formula CₙH₂ₙ₊₁ wherein n is 0 or an integer of from 1 to 16;

(20) a semiconductor blend according to (18), wherein said small molecule semiconductor material is a benzothiophene derivative of formula (VII) selected from the following groups:

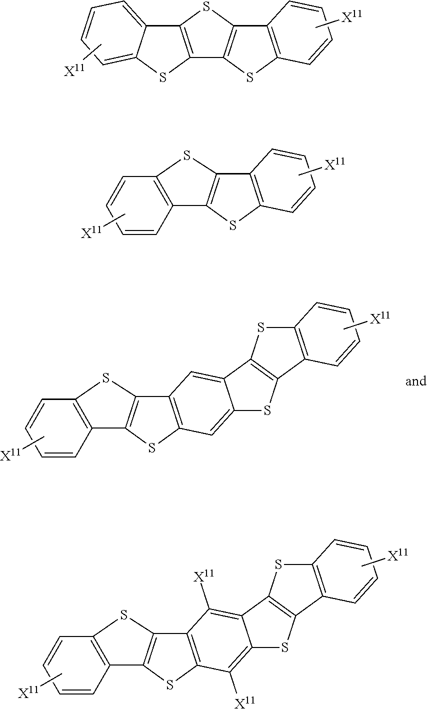

wherein X¹¹ is a group of formula CₙH₂ₙ₊₁ wherein n is an integer of from 4 to 16;

(21) a semiconductor blend according to (1), wherein:

said polymer material is a semiconducting conjugated polymer that comprises the repeat unit (I) as defined in (4), wherein R¹ and R² are the same or different and each is selected from the group consisting of an alkyl group having from 4 to 12 carbon atoms and a phenyl group, said phenyl group being unsubstituted or substituted with one or more substituents selected from an alkyl group having from 4 to 8 carbon atoms and an alkoxy group having from 4 to 8 carbon atoms, said semiconducting conjugated polymer further comprising the repeat unit of formula (II) as defined in (7) wherein each of Ar¹ and Ar² is a phenyl group and R³ is an alkyl group having from 1 to 8 carbon atoms or a phenyl group which may be unsubstituted or substituted with an alkyl group having from 1 to 8 carbon atoms;

said small molecule semiconductor material is a benzothiophene derivative of formula (VII):

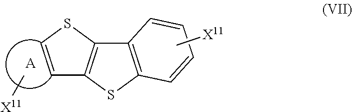

wherein A is a phenyl group or a thiophene group, said phenyl group or thiophene group being unfused or fused with a phenyl group or a thiophene group which can be unsubstituted or substituted with at least one group of formula X¹¹ and/or fused with a group selected from a phenyl group, a thiophene group and a benzothiophene group, any of said phenyl, thiophene and benzothiophene groups being unsubstituted or substituted with at least one group of formula X¹¹; and

each group X¹¹ may be the same or different and is selected from substituents X as defined in (10), and preferably is a group of formula CₙH₂ₙ₊₁ wherein n is 0 or an integer of from 1 to 20; and

said semiconductor blend comprises at least 75% by weight of said semiconducting conjugated polymer material;

(22) a semiconductor blend according to (21), wherein:

said semiconducting conjugated polymer material is TFB [9,9′-dioctylfluorene-co-N-(4-butylphenyl)-diphenylamine]ₙ;

said small molecule semiconductor material is a compound of formula (VII) as defined in (21) wherein A is selected from:

a thiophene group that is fused with a phenyl group substituted with at least one group of formula X¹¹;

a phenyl group that may be unsubstituted or substituted with at least one group of formula X¹¹, said phenyl group further being unfazed or fused with a thiophene group which can be unsubstituted or substituted with at least one group of formula X¹¹ and/or fused with a benzothiophene group, said benzothiophene group being unsubstituted or substituted with at least one group of formula X¹¹, wherein X¹¹ is a group of formula CₙH₂ₙ₊₁ wherein n is 0 or an integer of from 1 to 16; and

said semiconductor blend comprises at least 75% by weight of said semiconducting conjugated polymer material;

(23) a semiconductor blend according to (22), wherein said small molecule semiconductor material is selected from the following group:

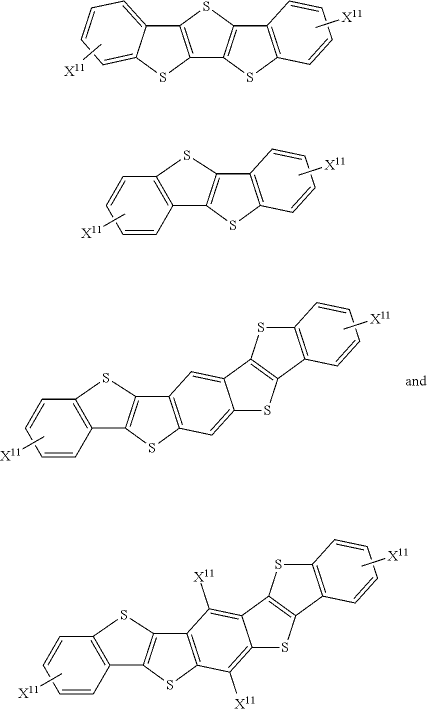

wherein X¹¹ is a group of formula CₙH₂ₙ₊₁ wherein n is an integer of from 4 to 16; and

said semiconductor blend comprises from 75-85% by weight of said semiconducting conjugated polymer material;

(24) a semiconductor blend according to (23) wherein said semiconducting conjugated polymer material is TFB [9,9′-dioctylfluorene-co-N-(4-butylphenyl)-diphenylamine]ₙ, said small molecule semiconductor material has the following formula:

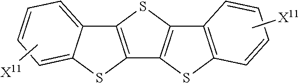

wherein X¹¹ is a group of formula CₙH₂ₙ₊₁ wherein n is an integer of from 4 to 16; and

said semiconductor blend comprises from 75-85% by weight of said semiconducting conjugated polymer material; and

(25) a semiconductor blend according to (24), wherein each group X¹¹ is a hexyl group and said semiconductor blend comprises 75% by weight of said semiconducting conjugated polymer material.

(26) In a further example, there is provided an ink comprising a blend of a polymer material and a small molecule semiconductor material dissolved or dispersed in a solvent, said blend comprising at least 70% by weight of polymer material, wherein the concentration of said blend in said solvent is chosen such that the saturation mobility of a deposited layer of said blend is at most 10% less than that obtained for a layer comprising a blend comprising a 50:50 mixture by weight of the same polymer material and the same small molecule semiconductor material deposited from an ink having a concentration in the same solvent that is half the concentration of said blend comprising at least 70% by weight of polymer material dissolved or dispersed in said solvent.

Preferred further examples include:

(27) an ink according to (26), wherein said blend comprises from 70 to 85% by weight of polymer material;

(28) an ink according to (26), wherein said blend comprises 75% by weight of polymer material;

(29) an ink according to any one of (26) to (28), wherein the concentration of said blend in said solvent is chosen such that the saturation mobility of a deposited layer of said blend is at most 5% less than that obtained for a layer comprising a blend comprising a 50:50 mixture by weight of the same polymer material and the same small molecule semiconductor material deposited from an ink having a concentration in the same solvent that is half the concentration of said blend comprising at least 70% by weight of polymer material dissolved or dispersed in said solvent;

(30) an ink according to any one of (26) to (28), wherein the concentration of said blend in said solvent is chosen such that the saturation mobility of a deposited layer of said blend is at least the same as that obtained for a layer comprising a blend comprising a 50:50 mixture by weight of the same polymer material and the same small molecule semiconductor material deposited from an ink having a concentration in the same solvent that is half the concentration of said blend comprising at least 70% by weight of polymer material dissolved or dispersed in said solvent;

(31) an ink according to any one of (26) to (30), wherein the concentration of said blend in said solvent is at least 0.6% w/v;

(32) an ink according to any one of (26) to (30), wherein the concentration of said blend in said solvent is at least 0.8% w/v;

(33) an ink according to any one of (26) to (32), wherein said polymer material is a semiconductor polymer material;

(34) an ink according to (33), wherein said semiconductor polymer material is a semiconductor polymer material according to any one of (4) to (9) above;

(35) an ink according to any one of (26) to (34), wherein said small molecule semiconductor material is a small molecule semiconductor material according to any one of (10) to (20);

(36) an ink according to any of (26) to (35), wherein said solvent is selected from the group consisting of methylbenzenes (such as toluene, xylene or trimethylbenzene), C₁₋₄ alkoxybenzenes and C₁₋₄ alkyl substituted C₁₋₄ alkoxybenzenes (such as anisole, methylanisole, di- or tri-methylanisole, di- or tri-methoxybenzene or ethoxybenzene), halogenated benzenes (such as mono-, di- or tri-chlorobenzene or bromobenzene, chloro or bromo toluene), non-aromatic compounds (such as decahydronaphthalene, octane, nonane, decane or dodecane), halogenated non-aromatic compounds (such as chloroform or dichloromethane) and fused benzenes (such as 1-methylnaphthalene or 1-methoxynaphthalene);

(37) an ink according to (36), wherein said solvent is selected from the group consisting of toluene, anisole, ethoxybenzene, chlorobenzene, decahydronaphthalene, octane, chloroform and 1-methylnaphthalene;

(38) an ink according to any one of (26) to (37), wherein:

said polymer material is a semiconducting conjugated polymer that comprises the repeat unit (I) as defined in (4), wherein R¹ and R² are the same or different and each is selected from the group consisting of an alkyl group having from 4 to 12 carbon atoms and a phenyl group, said phenyl group being unsubstituted or substituted with one or more substituents selected from an alkyl group having from 4 to 8 carbon atoms and an alkoxy group having from 4 to 8 carbon atoms, said semiconducting conjugated polymer further comprising the repeat unit of formula (II) as defined in (7) wherein each of Ar¹ and Ar² is a phenyl group and R³ is an alkyl group having from 1 to 8 carbon atoms or a phenyl group which may be unsubstituted or substituted with an alkyl group having from 1 to 8 carbon atoms;

said small molecule semiconductor material is a benzothiophene derivative of formula (VII):

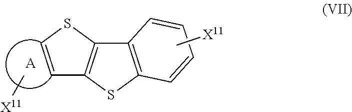

wherein A is a phenyl group or a thiophene group, said phenyl group or thiophene group being unfused or fused with a phenyl group or a thiophene group which can be unsubstituted or substituted with at least one group of formula X¹¹ and/or fused with a group selected from a phenyl group, a thiophene group and a benzothiophene group, any of said phenyl, thiophene and benzothiophene groups being unsubstituted or substituted with at least one group of formula X¹¹; and

each group X¹¹ may be the same or different and is selected from substituents X as defined in (10), and preferably is a group of formula CₙH₂ₙ₊₁ wherein n is 0 or an integer of from 1 to 20;

said semiconductor blend comprises at least 70% by weight of said polymer material;

said solvent is selected from the group consisting of toluene, anisole, ethoxybenzene, chlorobenzene, decahydronaphthalene, octane, chloroform and 1-methylnaphthalene;

wherein the concentration of said blend in said solvent is chosen such that the saturation mobility of a deposited layer of said blend is at most 10% less than that obtained for a layer comprising a blend comprising a 50:50 mixture by weight of the same polymer material and the same small molecule semiconductor material deposited from an ink having a concentration in the same solvent that is half the concentration of said blend comprising at least 70% by weight of polymer material dissolved or dispersed in said solvent;

(39) an ink according to (38), wherein:

said semiconducting conjugated polymer material is TFB [9,9′-dioctylfluorene-co-N-(4-butylphenyl)-diphenylamine]ₙ;

said small molecule semiconductor material is a compound of formula (VII) as defined in (38) wherein A is selected from:

a thiophene group that is fused with a phenyl group substituted with at least one group of formula X¹¹;

a phenyl group that may be unsubstituted or substituted with at least one group of formula X¹¹, said phenyl group further being unfused or fused with a thiophene group which can be unsubstituted or substituted with at least one group of formula X¹¹ and/or fused with a benzothiophene group, said benzothiophene group being unsubstituted or substituted with at least one group of formula X¹¹, wherein X¹¹ is a group of formula CₙH₂ₙ₊₁ wherein n is 0 or an integer of from 1 to 16;

said semiconductor blend comprises at least 70% by weight of said polymer material;

said solvent is selected from the group consisting of toluene, anisole, ethoxybenzene, chlorobenzene, decahydronaphthalene, octane, chloroform and 1-methylnaphthalene; and

wherein the concentration of said blend in said solvent is chosen such that the saturation mobility of a deposited layer of said blend is at most 5% less than that obtained for a layer comprising a blend comprising a 50:50 mixture by weight of the same polymer material and the same small molecule semiconductor material deposited from an ink having a concentration in the same solvent that is half the concentration of said blend comprising at least 70% by weight of polymer material dissolved or dispersed in said solvent;

(40) an ink according to (39), wherein said small molecule semiconductor material is selected from the following group:

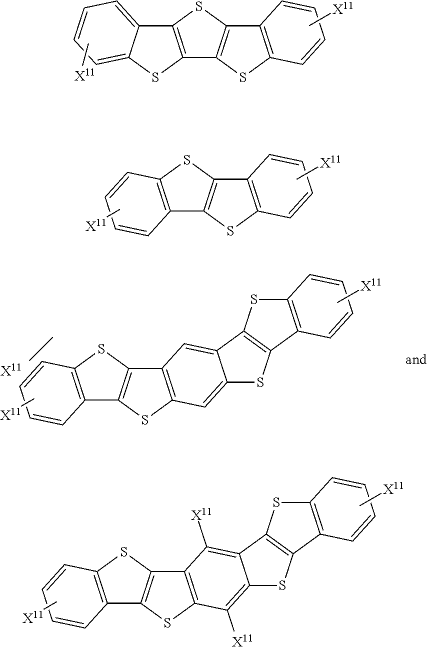

wherein X¹¹ is a group of formula CₙH₂ₙ₊₁ wherein n is an integer of from 4 to 16;

said semiconductor blend comprises from 70-85% by weight of said polymer material;

said solvent is selected from the group consisting of toluene, anisole, ethoxybenzene, chlorobenzene, decahydronaphthalene, octane, chloroform and 1-methylnaphthalene; and

wherein the concentration of said blend in said solvent is chosen such that the saturation mobility of a deposited layer of said blend is at least the same as that obtained for a layer comprising a blend comprising a 50:50 mixture by weight of the same polymer material and the same small molecule semiconductor material deposited from an ink having a concentration in the same solvent that is half the concentration of said blend comprising at least 70% by weight of polymer material dissolved or dispersed in said solvent; and

(41) an ink according to (39) to (40) wherein said semiconducting conjugated polymer material is TFB [9,9′-dioctylfluorene-co-N-(4-butylphenyl)-diphenylamine]ₙ, and said small molecule semiconductor material has the following formula:

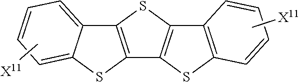

wherein X¹¹ is a group of formula CₙH₂ₙ₊₁ wherein n is an integer of from 4 to 16;

said semiconductor blend comprises at least 70% by weight of said semiconducting conjugated polymer material;

said solvent is selected from the group consisting of toluene, anisole, ethoxybenzene, chlorobenzene, decahydronaphthalene, octane, chloroform and 1-methylnaphthalene; and

the concentration of said semiconductor blend in said solvent is at least 0.6% w/v;

(42) an ink according to (41), wherein each group X¹¹ is a hexyl group and said semiconductor blend comprises 75% by weight of polymer material; and

the concentration of said semiconductor blend in said solvent is at least 0.8% w/v.

In a third aspect of the present invention there is provided a semiconductor blend deposited from an ink according to any one of (26) to (42). In a preferred embodiment, the blend is deposited from the ink by spin coating.

In a fourth aspect of the present invention, there is provided a semiconductor device wherein the semiconducting layer comprises a layer of a semiconductor blend, characterised in that said semiconductor blend is a semiconductor blend according to any one of (1) to (25). In a preferred embodiment of this fourth aspect of the invention, the device is an organic thin film transistor, the organic thin film transistor comprising source and drain electrodes with a channel region therebetween having a channel length, a gate electrode, a dielectric layer disposed between the source and drain electrodes and channel region and the gate electrode and a semiconducting layer, wherein said semiconducting layer comprises a layer of a semiconductor blend according to any one of (1) to (25).

In a fifth aspect of the present invention there is provided a semiconductor device wherein the semiconducting layer comprises a layer of a semiconductor blend, characterised in that said semiconductor blend is deposited from an ink according to any one of (26) to (42). In a preferred aspect, said device is an organic thin film transistor, the organic thin film transistor comprising source and drain electrodes with a channel region therebetween having a channel length, a gate electrode, a dielectric layer disposed between the source and drain electrodes and channel region and the gate electrode and a semiconducting layer, wherein said semiconducting layer comprises a layer of a semiconductor blend deposited from an ink according to any one of (26) to (42). Preferably, the semiconducting layer is deposited from said ink by spin coating.

### DETAILED DESCRIPTION OF THE INVENTION

Contrary to the teaching of the prior art, which states that for the production of semiconductor blends having a good performance, it is necessary to have at least 50% by weight of small molecule semiconductor, we have found that it is possible to produce blends comprising at least 75% by weight of polymer. The high performance of the polymer rich semiconductor blend is obtained by increasing the total solid content of the blend, such that a performance comparable to a small molecule rich blend is obtained.

By using a polymer rich blend (at least 70% polymer by mass), the mobility of organic thin film transistors (OTFTs) and other devices comprising a semiconductor layer can be improved by depositing said layer from an ink formulated with a higher total solid content of the semiconductor blend. The impact of controlling the total solid content in the ink has a key influence on the saturation mobility of devices, as semiconductor blends having at least 70% by mass of polymer that are deposited from inks at a low total solids concentration of the blend in the ink are found to have a low saturation mobility (as taught in the prior art), whereas if the same blend is deposited from a high concentration ink this is found to yield a significantly higher mobility (typically up to 1 order of magnitude higher). In the context of the present invention, total solid content of the semiconductor blend refers to the concentration of said blend in the ink measured as % w/v (i.e. weight of solid/volume of solvent).

WO 2004/057688, as discussed above, teaches that a blend system requires at the very least 30% by mass of the small molecule component in the blend (and that this gives poor results), and the best results are achieved for blends having a ratio of polymer:small molecule semiconductor of from 40:60 to 60:40. In the present invention, we have shown that blends containing 25% by weight of small molecule semiconductor or less can be used to attain high mobility devices. This is achieved by the use of inks having a much higher total solid content of the polymer, e.g. at least twice as high.

What the exact concentration of the blend in the ink should be will vary depending upon the amount of polymer in the blend, the chemical structure and molecular weight of the polymer and the chemical structure of the small molecule semiconductor and the desired mobility to be achieved in the blend. For example with a TFB polymer with a molecular weight of circa 300,000 where it is desired to have a similar saturation mobility to that achieved with a layer comprising a 75:25 blend of small molecule semiconductor A (structure below):TFB, the ink concentration required to deposit a layer comprising a 25:75 blend of small molecule semiconductor A:TFB to achieve a layer of semiconductor blend having a similar saturation mobility is 0.8% w/v in o-xylene, which is twice the concentration of the ink used to deposit the layer comprising the 75:25 small molecule semiconductor A:TFB blend.

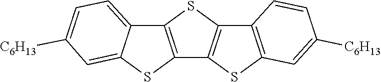

The present invention provides a significant advance over the prior art blends and inks as a lower quantity of small molecule material can be used for the blend system. This has two main advantages over the small molecule rich blend approach as follows:

(i) less small molecule material has to be used, thus potentially reducing the cost of the semiconductor blend material (as polymer synthesis is a more matured process); and

(ii) a lower effective concentration of the small molecule material is in solution, and hence the likelihood of crystallisation of the small molecule component in solution is reduced.

The polymer material used in the preparation of the blend according to the present invention can be an insulating or semiconductor material. It can be any polymer material suitable for the purpose of overcoming the low solubility and poor film forming properties of small organic semiconducting molecules, e.g. those known to the skilled person as described in the prior art such as Smith et. al., Applied Physics Letters, Vol 93, 253301 (2008); Ohe et. al., Applied Physics Letters, Vol 93, 053303 (2008); Madec et. al., Journal of Surface Science & Nanotechnology, Vol 7, 455-458 (2009); and Kang et. al., J. Am. Chem. Soc., Vol 130, 12273-75 (2008).

If it is a semiconducting polymer, it is preferably a conjugated polymer comprising a repeat unit of formula (I) as defined in (4) above. Preferably, said conjugated polymer comprising a repeat unit of formula (I) further comprises a repeat unit of formula (II) as defined in (7) above. Preferred semiconductor materials for use include TFB [9,9′-dioctylfluorene-co-N-(4-butylphenyl)-diphenylamine]ₙ.

The small molecule semiconductor material used in the preparation of the blend according to the present invention can be any small molecule semiconductor material suitable for the purpose, e.g. those known to the person skilled as described in the prior art above or the small molecule semiconductors described in WO2010/061176. Preferred examples of small molecule semiconductor materials for use in the present invention are organic semiconducting compounds of formulae (III) to (VII) as defined in (10) to (20) above. Particularly preferred are those as defined in (20).

In the polymers and small molecule semiconductors as defined in (4) to (9) and (10) to (20) respectively for use in the present invention, alkyl groups in the definitions of R¹, R², R³, Ar1 and Ar² are alkyl groups having from 1 to 16 carbons atoms, examples of which include methyl, ethyl, propyl, isopropyl and butyl.

In the polymers and small molecule semiconductors as defined in (4) to (9) and (10) to (20) respectively for use in the present invention, alkyl groups in the definitions of Ar³, Ar⁴, Ar⁵, Ar⁶, Ar⁷, Ar⁸, Ar⁹, X, X¹, X², R⁴ and R⁵ are alkyl groups having from 1 to 20 carbons atoms, examples of which include methyl, ethyl, propyl, isopropyl and butyl.

In the polymers and small molecule semiconductors as defined in (4) to (9) and (10) to (20) respectively for use in the present invention, aryl groups in the definitions of R¹, R², R³, Ar¹ and Ar² are aryl groups having from 5 to 14 carbon atoms. Examples include phenyl, indenyl, naphthyl, phenanthrenyl and anthracenyl groups. More preferred aryl groups include phenyl groups.

In the polymers and small molecule semiconductors as defined in (4) to (9) and (10) to (20) respectively for use in the present invention, heteroaryl groups in the definitions of R¹, R², Ar¹ and Ar² are 5- to 7-membered heteroaryl groups containing from 1 to 3 sulfur atoms, oxygen atoms and/or nitrogen atoms and of Ar³, Ar⁴, Ar⁵, Ar⁶, Ar⁷, Ar⁸ and Ar⁹ Are 5- to 7-membered heteroaryl groups containing from 1 to 3 sulfur atoms, oxygen atoms, selenium atoms and/or nitrogen atoms. Examples include furyl, thienyl, pyrrolyl, azepinyl, pyrazolyl, imidazolyl, oxazolyl, isoxazolyl, thiazolyl, isothiazolyl, 1,2,3-oxadiazolyl, triazolyl, tetrazolyl, thiadiazolyl, pyranyl, pyridyl, pyridazinyl, pyrimidinyl and pyrazinyl groups. More preferred heteroaryl groups include furyl, thienyl, pyrrolyl and pyridyl, and most preferred is thienyl.

In the polymers and small molecule semiconductors as defined in (4) to (9) and (10) to (20) respectively for use in the present invention, alkoxy groups in the definitions of R¹, R², R³, Ar¹ and Ar² are alkoxy groups having from 1 to 16 carbons atoms, examples of which include methoxy, ethoxy, propoxy, isopropoxy and butoxy.

In the polymers and small molecule semiconductors as defined in (4) to (9) and (10) to (20) respectively for use in the present invention, alkoxy groups in the definitions of X, X¹, X², R⁴ and R⁵ are alkoxy groups having from 1 to 12 carbons atoms, examples of which include methoxy, ethoxy, propoxy, isopropoxy and butoxy.

In the polymers and small molecule semiconductors as defined in (4) to (9) and (10) to (20) respectively for use in the present invention, alkenyl groups in the definitions of X, X¹, X², R⁴ and R⁵ are alkenyl groups having from 2 to 12 carbon atoms, examples of which include ethenyl, propenyl and 2-methylpropenyl.

In the polymers and small molecule semiconductors as defined in (4) to (9) and (10) to (20) respectively for use in the present invention the unsubstituted or substituted amino groups in the definitions of X, X¹, X², R⁴ and R⁵ are amino groups that may be unsubstituted or substituted with one or two alkyl groups that may be the same or different, each having from 1 to 8 carbon atoms, preferably from 1 to 4 carbon atoms. Preferred examples include amino, methylamino, ethylamino and methylethylamino.

In the compounds of formulae (III) to (VI) according to (10) to (17) above, the alkyl groups are straight, branched or cyclic groups having from 1 to 20 carbon atoms and they may be unsubstituted or substituted. Exemplary substituents include alkoxy groups having from 1 to 12 carbon atoms, halogen atoms, amino groups that may be unsubstituted or substituted with one or two alkyl groups that may be the same or different and each having from 1 to 8 carbon atoms, acylamino groups having from 2 to 12 carbon atoms, nitro groups, alkoxycarbonyl groups having from 2 to 7 carbon atoms, carboxyl groups, aryl groups having from 5 to 14 carbon atoms and 5- to 7-membered heteroaryl groups containing from 1 to 3 sulfur atoms, oxygen atoms, selenium atoms, and/or nitrogen atoms.

In the compounds of formulae (III) to (VI) according to (10) to (13) above, the Ar³, Ar⁴, Ar⁵, Ar⁶, Ar⁷, Ar⁸ and Ar⁹ comprise monocyclic aromatic rings. These are preferably selected from 5- to 7-membered heteroaryl groups containing from 1 to 3 sulfur atoms, oxygen atoms, selenium atoms and/or nitrogen atoms; the monocyclic rings are more preferably selected from phenyl, indenyl, naphthyl, phenanthrenyl, anthracenyl, furyl, thienyl, pyrrolyl and pyridyl, and most preferably phenyl or thienyl.

Solvents suitable for use in the preparation of the inks of the present invention include methylbenzenes (such as toluene, xylene or trimethylbenzene), C₁₋₄ alkoxybenzenes and C₁₋₄ alkyl substituted C₁₋₄ alkoxybenzenes (such as anisole, methylanisole, di-, tri-methylanisole, di-, tri-methoxybenzene or ethoxybenzene), halogenated benzenes (such as mono-, di- or tri-chlorobenzene or bromobenzene, chloro or bromo toluene), non-aromatic compounds (such as decahydronaphthalene, octane, nonane, decane or dodecane), halogenated non-aromatic compounds (such as chloroform or dichloromethane) and fused benzenes (such as 1-methylnaphthalene or 1-methoxynaphthalene).

Solvents particularly suitable for use in the preparation of the inks of the present invention are any solvents that can dissolve the polymers and small molecule semiconductors of the invention, allow the blends to be deposited in a conventional manner (e.g. spin coating) and then evaporate. Particularly preferred solvents are C₁₋₄ alkoxybenzenes and C₁₋₄ alkyl substituted C₁₋₄ alkoxybenzenes.

C₁₋₄ alkoxybenzenes are benzene groups substituted by an alkoxy group having from 1 to 4 carbon atoms, examples of which include methoxybenzene, ethoxybenzene, propoxybenzene, isopropoxybenzene and butoxybenzene. Preferred examples are anisole and ethoxybenzene, and anisole is particularly preferred.

C₁₋₄ alkyl substituted C₁₋₄ alkoxybenzenes are the above alkoxybenzenes that are substituted with a single alkyl group having from 1 to 4 carbon atoms, examples of which include methyl, ethyl, propyl, isopropyl and butyl groups. Preferred C₁₋₄ alkyl substituted C₁₋₄ alkoxybenzenes include anisole substituted in the 2-, 3- or 4-position by a methyl or ethyl group and ethoxybenzene substituted in the 2-, 3- or 4-position by a methyl or ethyl group. 2-Methylanisole and 4-methylanisole are particularly preferred.

The organic thin film transistors according to the invention may be any organic thin film transistor that comprises an organic semiconductor layer. The transistors can be p-type or n-type. Suitable transistor configurations include top-gate transistors and bottom-gate transistors. The architecture of these is discussed in the background of the invention.

The present invention may be further understood by consideration of the following examples with reference to the following drawings.

### BRIEF DESCRIPTION OF THE FIGURES

FIG. 1 shows a top gate, bottom contact thin film transistor;

FIG. 2 shows a bottom gate, bottom contact thin film transistor;

FIG. 3 shows the polymer component TFB and the small molecule semiconductor component A used in the preparation of the semiconducting blends prepared in the examples of the present application;

FIG. 4 is a schematic depiction of a top gate organic thin film transistor prepared according to the present invention;

FIG. 5 is a plot of saturation mobility (cm²/Vs) (taken in the saturation regime of the device) against channel length (μm) measured for devices obtained using blends according to the present invention and other blends that are outside the scope of the invention; and

FIG. 6 is a plot of average saturation mobility (cm²/Vs) against the % by weight of the small molecule semiconductor small molecule semiconductor A in the semiconducting blend measured for devices according to the present invention.

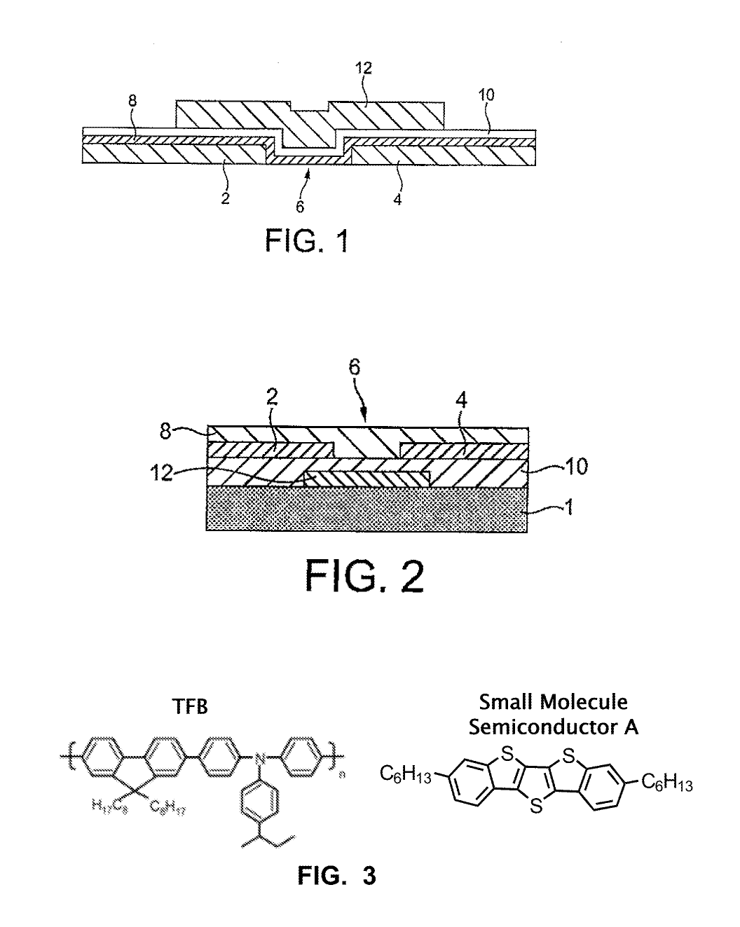

### EXAMPLES

The following examples focus on the use of certain blends of the present invention for obtaining high mobility organic thin film transistor (OTFT) devices. Two specific examples of a small molecule—polymer blend system are given as working examples based on device results obtained in a top gate, bottom contact device configuration prepared according to the following preparative procedure.

### TFT Fabrication

### Pre-Cleaning of OTFT Substrates and Self Assembled Monolayer (SAM) Pre-Treatments

The first step in fabrication of the device requires the pre-cleaning of the device substrates and the application of self assembled monolayers in order to ensure that a uniform surface energy is obtained in the channel region and the contact resistance is minimised. The substrates consist of gold source and drain electrodes deposited directly on top of the glass surface. The substrates were cleaned by oxygen plasma to ensure any residual photoresist material (used for the source-drain electrode definition) is removed.

After the plasma treatment, a channel region SAM (phenethyl-trichlorosilane) was applied from a solution phase in toluene at a concentration of 20 mM by flooding the substrate in the toluene solution for a period of 2 minutes. The solution was removed by spinning the substrate on a spin coater, then rinsing it in toluene followed by isopropanol. The same process was repeated to apply the electrode SAM material (pentafluorobenzenethiol) at the same concentration in isopropanol for a period of 2 minutes. Again, the substrate was rinsed in isopropanol to remove any unreacted material from the substrate. All of these steps were performed in air. Samples were then transported to a dry nitrogen environment and baked at 60° C. for 10 minutes to ensure the samples were dehydrated.

### Preparation and Spin-Coating of the Semiconductor Blend Material Solution

In this disclosure we consider five types of semiconductor blends to highlight the importance of the formulation of the low volume content small molecule semiconductor blends (see Table 1 below).

The blends of small molecule and polymer materials were prepared by firstly preparing separate solutions (separate inks) of the individual components (TFB and small molecule semiconductor A) in anhydrous o-xylene to desired concentrations (% w/v) and then mixing these individual inks by volume.

TABLE 1

| | | | Effective small |
|---|---|---|---|
| | Component Ratio | | molecule |
| | (small molecule | | semiconductor A |
| | semiconductor | Ink Concentration | Concentration in |
| Blend sample | A/TFB) | (% w/v) | Blend (mg/ml) |
| S5 | 75/25 | 0.4 | 3 |
| S1 | 50/50 | 0.4 | 2 |
| S2 | 25/75 | 0.4 | 1 |
| S3 | 25/75 | 0.6 | 1.5 |
| S4 | 25/75 | 0.8 | 2 |

For each blend, the individual components were prepared in solution to the respective ink concentration of the blend, e.g. a 0.4% w/v corresponds to 4 mg of solid (TFB and small molecule A) in 1 ml of solvent, 0.8% w/v corresponds to 8 mg solid per 1 ml of solvent. The components were then mixed by volume to attain the target blend ratio.

Deposition of each blend was made using a spin coater at a coating speed of 600 rpm for a period of 30 seconds, then dried at 80° C. for a period of 10 minutes. A dielectric layer was then deposited on this semiconductor film.

### Deposition of the Dielectric Layer

The dielectric material used was the fluorinated polymer polytetrafluoroethylene (PTFE). Other suitable fluorinated polymers that could have been used include perfluoro cyclo oxyaliphatic polymer (CYTOP), perfluoroalkoxy polymer resin (PFA), fluorinated ethylene-propylene (FEP), polyethylenetetrafluoroethylene (ETFE), polyvinylfluoride (PVF), polyethylenechlorotrifluoroethylene (ECTFE), polyvinylidene fluoride (PVDF), polychlorotrifluoroethylene (PCTFE), perfluoro elastomers (FFKM) such as Kalrez® or Tecnoflon®, fluoro elastomers such as Viton®, Perfluoropolyether (PFPE) and a polymer of tetrafluoroethylene, hexafluoropropylene and vinylidene fluoride (THV).

Fluorinated polymers are an attractive choice for the dielectric material, particularly in the field of organic thin film transistors (OTFTs), because they possess a number of favourable properties including:—

(i) Excellent spin coating properties, for instance: (a) wetting on a wide variety of surfaces; and (b) film formation, with the option of doing multi-layer coatings.

(ii) Chemical inertness.

(iii) Quasi-total solvent orthogonality: consequently, the risk of the organic semiconducting layer being dissolved by the solvent used for spin-coating the dielectric is minimal.

(iv) High hydrophobicity: this can be advantageous because it results in low water uptake and low mobility of ionic contaminants in the fluorinated polymer dielectric (resulting in low hysteresis).

### Deposition of the Gate Electrode

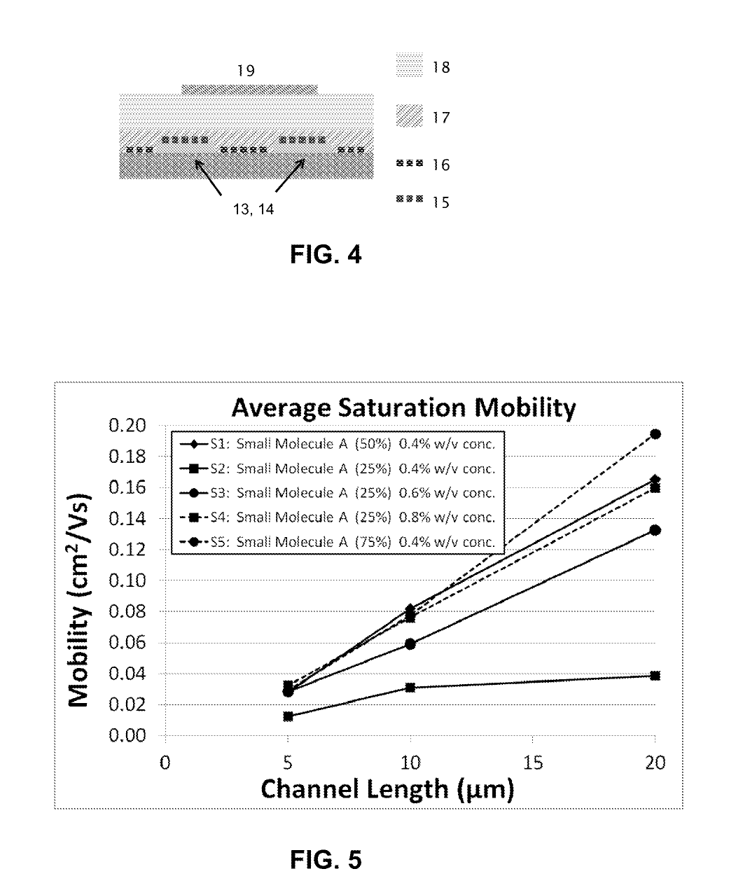

Finally the gate electrode was deposited by thermal evaporation of 5 nm chrome followed by 200 nm aluminium through a shadow mask to give the desired organic thin film transistor, as shown in schematic form in FIG. 4, wherein 13 and 14 are the source and drain electrodes, 15 is the electrode SAM, 16 is the channel SAM, 17 is the semiconductor blend layer, 18 is the dielectric layer and 19 is the gate electrode.

### Device Characterisation

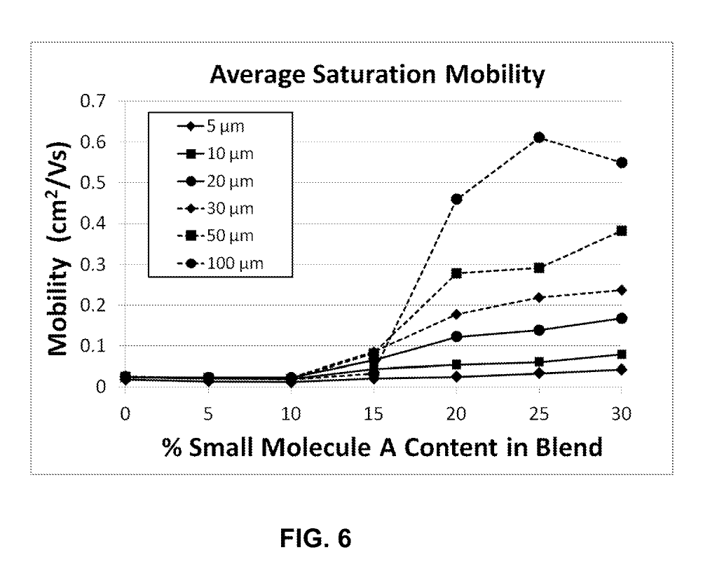

Devices produced as described above were measured in ambient conditions (no device encapsulation was used) using a Hewlett Packard 4156C semiconductor parameter analyser by measuring output and transfer device characteristics. Device mobility was calculated from the transfer data in the saturation regime. The saturation mobility as shown in the titles of the FIGS. 5 and 6 discussed below refers to the saturation regime mobility, where the drain electrode is biased at −40V with reference to the source electrode. In this regime, the drain current is said to be “saturated” with respect to the drain bias, such that a higher drain bias does not result in a higher drain current. Furthermore, the mobility is a measure of how much current is delivered through the device, and does not necessarily refer to the intrinsic mobility of the semiconductor material itself (although in many instances this is true). For example, a device with the same semiconductor material in the channel region may exhibit a higher contact resistance as compared to another device, therefore exhibiting a lower “device” mobility.

### Example 1

The saturation mobility as a function of channel length for all five semiconductor blends was measured as described above. The results are shown for each of the blends in FIG. 5. The mobility for short channel length devices (i.e. 10 μm and less) is of most interest for applications from the point of view of maximising the resolution of a display. The reduction in mobility with reducing channel length is a consequence of the presence of contact resistance in the devices (this is manifested at the interface between semiconductor and source or drain electrodes).

Considering devices made using blend samples S5, S1 and S2 devices first, it is observed that either a 75% (S5) or 50% content (S1) of the small molecule component in the blend give very similar mobility performance. However, the 25% small molecule blend (S2) devices exhibit a substantially lower mobility at all channel lengths by a factor 2 to 3. Considering the results reported in prior art document WO 2004/057688, where it is reported that the small molecule component should be at least 30% by mass in the blend, this appears to be a predictable result due to the low content of the small molecule material in the blend.

Now, turning to the same ratio of polymer and small molecule components in the blend as in S2 (i.e. 75:25 TFB:small molecule semiconductor A) but with an increased total solid content of the blend solution as in S3 and S4, the data shown in FIG. 5 shows that the device mobility can be recovered to the original level as observed in the small molecule rich blend (i.e. 75% small molecule semiconductor A-S5).

The high device mobility of a blend having a low small molecule content is in contrast to that shown in the prior art such as WO 2004/057688, where at least 30% by mass of the small molecule component is required in order to achieve high mobility devices. Whilst not wishing to be bound by theory, we believe this may arise from the need to have a good coverage of small molecule at the surface of the film in order to obtain high mobility devices. When blends having a low content of small molecule are deposited from low concentration inks, there is simply not enough small molecule in the resultant film to form a good small molecule layer. By increasing the solid (TFB and small molecule A) content of the semiconductor blend, there is then enough small molecule material to form this critical layer.

Advantages of the approach of using the low small molecule content blends of the present invention include the potential for improved solution stability and reduced cost of material. An improved solution stability can be realised if the solubility of the small molecule component is low with respect to the polymer material. In this case, at room temperature, the small molecule semiconductor is less likely to crystallise in or fall from solution if the blend is polymer rich than small molecule rich.

### Example 2

In this example, the average saturation mobility for devices prepared as described above was measured for blends having differing amounts of small molecule semiconductor A in the blend in order to determine the effect on the saturation mobility of the small molecule semiconductor A content in the blend. The results obtained are shown in FIG. 6. As can be seen from FIG. 6, for the blends of small molecule semiconductor A and TFB superior saturation mobilities are achieved when the small molecule semiconductor A fraction is from 15 to 30% in the polymer rich semiconductor blend.

### Example 3

The same procedures are done in the same way as in Examples 1 and 2 except that in place of small molecule semiconductor A, we substitute the same amounts of the following small molecule semiconductor B to prepare OTFT devices having blends at differing ratios of small molecule semiconductor B: TFB.

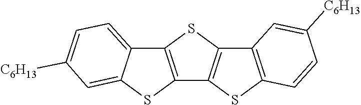

The saturation mobility as a function of channel length for all semiconductor blends is measured as described above, as is the saturation mobility for a device prepared as described above for blends having differing amounts of small molecule semiconductor A in the blend in order to determine the effect on the saturation mobility of the small molecule semiconductor A content in the blend.

Various modifications and improvements may be made without departing from the scope of the invention herein described. For example, ink jet printing or flexographic printing may be used in place of spin coating for device fabrication.

1. An ink for inkjet printing or spin coating, comprising a blend of a polymer material and a small molecule semiconductor material dissolved or dispersed in a solvent, said blend comprising at least 70% by weight of said polymer material and wherein the ink concentration is at least 0.4% w/v.

2. An ink according to claim 1, wherein said blend comprises at least 75% by weight of said polymer material.

3. An ink according to claim 1, wherein said blend comprises at least 80% by weight of said polymer material.

4. An ink according to claim 1, wherein the ink concentration is at least 0.6% w/v.

5. An ink according to claim 1, wherein the ink concentration is at least 0.8% w/v.

6. An ink according to claim 1, wherein said polymer material is a semiconducting polymer material.

7. An ink according to claim 6, wherein said semiconducting polymer material is a conjugated polymer comprising a repeat unit of formula (I) 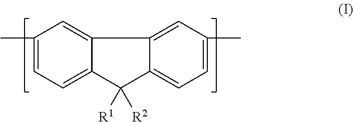
wherein R¹ and R² are the same or different and each is selected from the group consisting of hydrogen, an alkyl group having from 1 to 16 carbon atoms, an aryl group having from 5 to 14 carbon atoms and a 5- to 7-membered heteroaryl group containing from 1 to 3 sulfur atoms, oxygen atoms and/or nitrogen atoms, said aryl group or heteroaryl group being unsubstituted or substituted with one or more substituents selected from an alkyl group having from 1 to 16 carbon atoms and an alkoxy group having from 1 to 16 carbon atoms.

8. An ink according to claim 7, wherein said semiconducting polymer material is a conjugated polymer comprising the repeat unit (I), wherein R¹ and R² are the same or different and each is selected from the group consisting of hydrogen, an alkyl group having from 1 to 12 carbon atoms and a phenyl group, said phenyl group being unsubstituted or substituted with one or more substituents selected from an alkyl group having from 1 to 12 carbon atoms and an alkoxy group having from 1 to 12 carbon atoms.

9. An ink according to claim 7, wherein said semiconducting polymer material is a conjugated polymer comprising the repeat unit (I), wherein R¹ and R² are the same or different and each is selected from the group consisting of an alkyl group having from 4 to 12 carbon atoms and a phenyl group, said phenyl group being unsubstituted or substituted with one or more substituents selected from an alkyl group having from 4 to 8 carbon atoms and an alkoxy group having from 4 to 8 carbon atoms.

10. An ink according to claim 7, wherein said semiconducting polymer material is a conjugated polymer comprising the repeat unit (I), said polymer further comprising a repeat unit of formula (II): 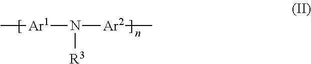
wherein Ar¹ and Ar² are the same or different and each is selected from the group consisting of an aryl group having from 5 to 14 carbon atoms and a 5- to 7-membered heteroaryl group containing from 1 to 3 sulfur atoms, oxygen atoms and/or nitrogen atoms, said aryl group or heteroaryl group optionally being substituted with one or more substituents selected from an alkyl group having from 1 to 16 carbon atoms and an alkoxy group having from 1 to 16 carbon atoms;
R³ is an alkyl group having from 1 to 16 carbon atoms, or an aryl group having from 5 to 14 carbon atoms which is unsubstituted or substituted with one or more substituents selected from an alkyl group having from 1 to 16 carbon atoms and an alkoxy group having from 1 to 16 carbon atoms;
and n is an integer greater than or equal to 1.

11. An ink according to claim 10, wherein each of Ar¹ and Ar² is a phenyl group and R³ is an alkyl group having from 1 to 8 carbon atoms or a phenyl group which may be unsubstituted or substituted with an alkyl group having from 1 to 8 carbon atoms.

12. An ink according to claim 10, wherein said semiconducting polymer material is TFB [9,9′-dioctylfluorene-co-N-(4-butylphenyl)-diphenylamine]ₙ.

13. An ink according to claim 1, wherein said small molecule semiconductor material is selected from the group consisting of substituted pentacenes and organic semiconducting compounds of formula (III): 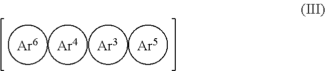
wherein Ar³, Ar⁴, Ar⁵ and Ar⁶ independently comprise monocyclic aromatic rings and at least one of the group consisting of Ar³, Ar⁴, Ar⁵ and Ar⁶ is substituted with at least one substituent X, which in each occurrence may be the same or different and is selected from the group consisting of (i) unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms, and (ii) a polymerizable or reactive group selected from the group consisting of halogens, boronic acids, diboronic acids and esters of boronic acids and diboronic acids, alkylene groups having from 2 to 12 carbon atoms and stannyl groups, and wherein Ar³, Ar⁴, Ar⁵ and Ar⁶ may each optionally be fused to one or more further monocyclic aromatic rings, and wherein at least one of the group consisting of Ar³, Ar⁴, Ar⁵ and Ar⁶ comprises a 5- to 7-membered heteroaryl group containing from 1 to 3 sulfur atoms, oxygen atoms, selenium atoms, and/or nitrogen atoms.

14. An ink according to claim 13, wherein Ar⁵ is fused to a further aryl group Ar⁷ to provide a structure of formula (IV): 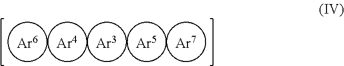
wherein Ar⁷ represents a monocyclic aromatic ring unsubstituted or substituted with one or more substituents X.

15. An ink according to claim 14, wherein Ar⁶ is fused to a further aryl group Ar⁸ to provide a structure of formula (V): 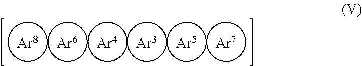
wherein Ar⁸ represents a monocyclic aromatic ring unsubstituted or substituted with one or more substituents X.

16. An ink according to claim 15, wherein Ar⁷ is fused to a further aryl group Ar⁹ to provide a structure of formula (VI): 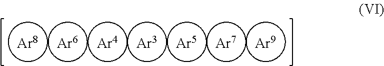
wherein Ar⁹ represents a monocyclic aromatic ring unsubstituted or substituted with one or more substituents X.

17. An ink according to claim 13, wherein the small molecule semiconductor material comprises the structure: 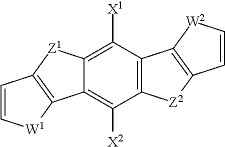
wherein X¹ and X² may be the same or different and are selected from the group consisting of (i) unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms, and (ii) polymerizable or reactive groups selected from the group consisting of halogens, boronic acids, diboronic acids and esters of boronic acids and diboronic acids, alkylene groups having from 2 to 12 carbon atoms and stannyl groups; Z¹ and Z² are independently S, O, Se or NR⁴; and W¹ and W² are independently S, O, Se, NR⁴ or —CR⁴═CR⁴—, where R⁴ is H or a substituent selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms.

18. An ink according to according to claim 13, wherein the small molecule semiconductor material comprises the structure: 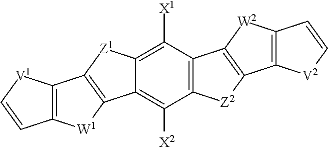
wherein X¹ and X² may be the same or different and are selected from the group consisting of (i) unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms, and (ii) polymerizable or reactive groups selected from the group consisting of halogens, boronic acids, diboronic acids and esters of boronic acids and diboronic acids, alkylene groups having from 2 to 12 carbon atoms and stannyl groups, Z¹ and Z² are independently S, O, Se or NR⁴; and W¹ and W² are independently S, O, Se, NR⁴ or —CR⁴═CR⁴—, where R⁴ is H or a substituent selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms and V₁ and V₂ are independently S, O, Se or NR⁵ wherein R⁵ is H or a substituent selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms.

19. An ink according to claim 13, wherein the small molecule semiconductor material comprises the structure: 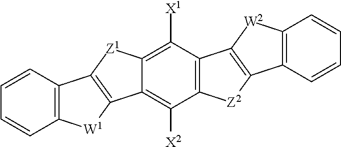
wherein X¹ and X² may be the same or different and are selected from the group consisting of (i) unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms, and (ii) polymerizable or reactive groups selected from the group consisting of halogens, boronic acids, diboronic acids and esters of boronic acids and diboronic acids, alkylene groups having from 2 to 12 carbon atoms and stannyl groups and Z¹ and Z² are independently S, O, Se or NR⁴; and W¹ and W² are independently S, O, Se, NR⁴ or —CR⁴═CR⁴—, where R⁴ is H or a substituent selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms.

20. An ink according to claim 13, wherein the small molecule semiconductor material comprises the structure: 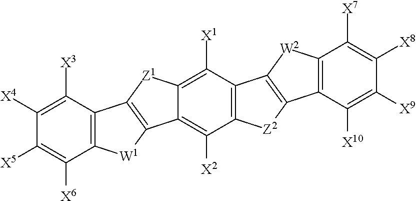
wherein Z¹ and Z² are independently S, O, Se or NR⁴; and W¹ and W² are independently S, O, Se, NR⁴ or —CR⁴═CR⁴—, where R⁴ is H or a substituent selected from the group consisting of unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms and X¹-X¹⁰, which may be the same or different, are selected from the group consisting of (i) unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms, and (ii) polymerizable or reactive groups selected from the group consisting of halogens, boronic acids, diboronic acids and esters of boronic acids and diboronic acids, alkylene groups having from 2 to 12 carbon atoms and stannyl groups.

21. An ink according to claim 13, wherein said small molecule semiconductor material is a benzothiophene derivative of formula (VII): 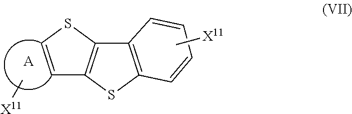
wherein A is a phenyl group or a thiophene group, said phenyl group or thiophene group being unfused or fused with a phenyl group or a thiophene group which can be unsubstituted or substituted with at least one group of formula X¹¹ and/or fused with a group selected from a phenyl group, a thiophene group and a benzothiophene group, any of said phenyl, thiophene and benzothiphene groups being unsubstituted or substituted with at least one group of formula X¹¹; and
each group X¹¹ may be the same or different and is selected from the group consisting of (i) unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms, and (ii) polymerizable or reactive groups selected from the group consisting of halogens, boronic acids, diboronic acids and esters of boronic acids and diboronic acids, alkylene groups having from 2 to 12 carbon atoms and stannyl groups.

22. An ink according to claim 21, wherein said small molecule semiconductor material is a benzothiophene derivative of formula (VII) wherein A is selected from:
a thiophene group that is fused with a phenyl group substituted with at least one group of formula X¹¹; or
a phenyl group that may be unsubstituted or substituted with at least one group of formula X¹¹, said phenyl group further optionally being fused with a thiophene group which can be unsubstituted or substituted with at least one group of formula X¹¹ and/or fused with a benzothiophene group, said benzothiphene group being unsubstituted or substituted with at least one group of formula X¹¹, wherein X¹¹ is a group of formula CₙH₂ₙ₊₁ wherein n is 0 or an integer of from 1 to 16.

23. An ink according to claim 21, wherein said small molecule semiconductor material is a benzothiophene derivative of formula (VII) selected from the following group: 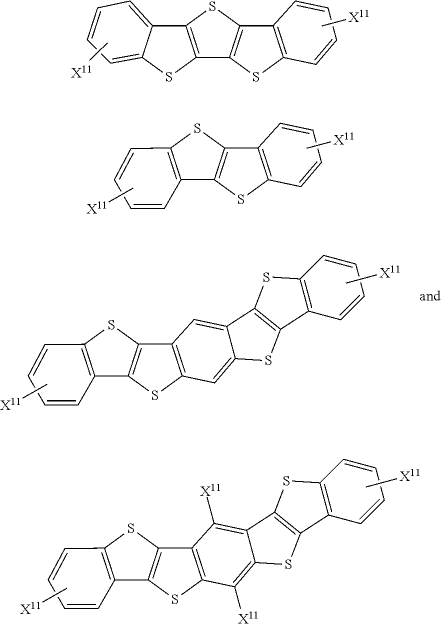
wherein X¹¹ is a group of formula CₙH₂ₙ₊₁ wherein n is an integer of from 4 to 16.

24. An ink according to claim 1, wherein:
said polymer material is a semiconducting conjugated polymer comprising a repeat unit of formula (I) 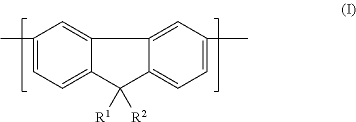
wherein R¹ and R² are the same or different and each is selected from the group consisting of an alkyl group having from 4 to 12 carbon atoms and a phenyl group, said phenyl group being unsubstituted or substituted with one or more substituents selected from an alkyl group having from 4 to 8 carbon atoms and an alkoxy group having from 4 to 8 carbon atoms, said semiconducting conjugated polymer further comprising a repeat unit of formula (II): 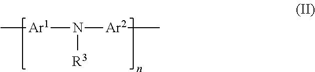
wherein each of Ar¹ and Ar² is a phenyl group and R³ is an alkyl group having from 1 to 8 carbon atoms or a phenyl group which may be unsubstituted or substituted with an alkyl group having from 1 to 8 carbon atoms;
said small molecule semiconductor material is a benzothiophene derivative of formula (VII): 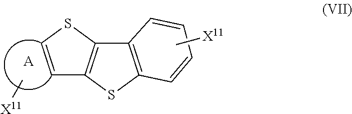
wherein A is a phenyl group or a thiophene group, said phenyl group or thiophene group optionally being fused with a phenyl group or a thiophene group which can be unsubstituted or substituted with at least one group of formula X¹¹ and/or fused with a group selected from a phenyl group, a thiophene group and a benzothiophene group, any of said phenyl, thiophene and benzothiophene groups being unsubstituted or substituted with at least one group of formula X¹¹; and
each group X¹¹ may be the same or different and is selected from the group consisting of (i) unsubstituted or substituted straight, branched or cyclic alkyl groups having from 1 to 20 carbon atoms, alkoxy groups having from 1 to 12 carbon atoms, amino groups that may be unsubstituted or substituted with one or two alkyl groups having from 1 to 8 carbon atoms, each of which may be the same or different, amido groups, silyl groups and alkenyl groups having from 2 to 12 carbon atoms, and (ii) polymerizable or reactive groups selected from the group consisting of halogens, boronic acids, diboronic acids and esters of boronic acids and diboronic acids, alkylene groups having from 2 to 12 carbon atoms and stannyl groups.

25. An ink according to claim 24, wherein:
said semiconducting conjugated polymer is TFB [9,9′-dioctylfluorene-co-N-(4-butylphenyl)-diphenylamine]ₙ;
said small molecule semiconductor material is a benzothiophene derivative of formula (VII): 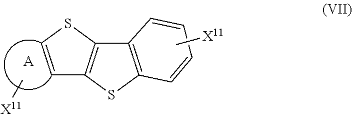
wherein A is selected from:
a thiophene group that is fused with a phenyl group substituted with at least one group of formula X¹¹;
a phenyl group that may be unsubstituted or substituted with at least one group of formula X¹¹, said phenyl group further optionally being fused with a thiophene group which can be unsubstituted or substituted with at least one group of formula X¹¹ and/or fused with a benzothiophene group, said benzothiophene group being unsubstituted or substituted with at least one group of formula X¹¹, wherein X¹¹ is a group of formula CₙH₂ₙ₊₁ wherein n is 0 or an integer of from 1 to 16.

26. An ink according to claim 25, wherein said small molecule semiconductor material is selected from the group consisting of the following formulae: 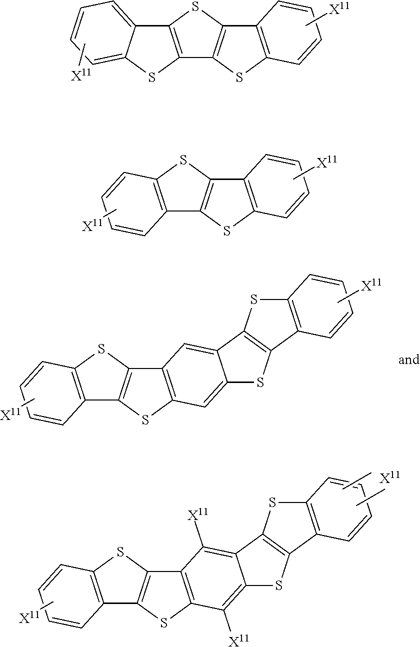
wherein X¹¹ is a group of formula CₙH₂ₙ₊₁ wherein n is an integer of from 4 to 16.

27. An ink according to claim 26, wherein said semiconducting conjugated polymer material is TFB [9,9′-dioctylfluorene-co-N-(4-butylphenyl)-diphenylamine]ₙ, and said small molecule semiconductor material has the following formula: 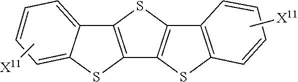
wherein X¹¹ is a group of formula CₙH₂ₙ₊₁ wherein n is an integer of from 4 to 16.

28. An ink according to claim 27, wherein each group X¹¹ is a hexyl group.

29. An ink according to claim 1, wherein said solvent is selected from the group consisting of C₁₋₄ alkoxybenzenes and C₁₋₄ alkyl substituted C₁₋₄ alkoxybenzenes.

30. An ink according to claim 29, wherein said solvent is selected from the group consisting of anisole, 2-methylanisole and 4-methylanisole.

31. A method of making an ink according to claim 33, wherein said polymer material is TFB [9,9′-dioctylfluorene-co-N-(4-butylphenyl)-diphenylamine]ₙ, and said small molecule semiconductor material has the following formula: 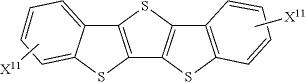
wherein X¹¹ is a group of formula CₙH₂ₙ₊₁ wherein n is an integer of from 4 to 16.

32. A method of making an ink according to claim 31, wherein each group X¹¹ is a hexyl group.

33. A method of making an ink as claimed in claim 1, said method comprising blending a first solution of the small molecule semiconductor in a solvent and a further solution of the polymer material in the same solvent, wherein said blend comprises at least 70% by weight of said polymer material and wherein the ink concentration is at least 0.4% w/v.
